(19) United States
(12) Patent Application Publication
(10) Pub. No.: US 2022/0018012 A1
(43) Pub. Date: Jan. 20, 2022

(54) CORROSION RESISTANT COATINGS

(71) Applicant: Oerlikon Surface Solutions AG, Pfäffikon, Pfäffikon (CH)

(72) Inventors: Lin SHANG, Bad Ragaz (CH); Juergen RAMM, Maienfeld (CH); Beno WIDRIG, Bad Ragaz (CH); Carmen JERG, Feldkirch (AT); Mirjam ARNDT, Wetzlar (DE)

(21) Appl. No.: 17/292,443

(22) PCT Filed: Nov. 5, 2019
(86) PCT No.: PCT/EP2019/000304

§ 371 Date: May 9, 2021

Related U.S. Application Data
(60) Provisional application No. 62/853,323, filed on May 28, 2019.
(60) Provisional application No. 62/757,279, filed on Nov. 8, 2018.

(51) Int. Cl. C23C 14/08; C23C 14/06; C23C 14/32; C23C 14/58

(52) U.S. Cl. CPC C23C 14/083; C23C 14/0641; C23C 14/0021; C23C 14/5806; C23C 14/325

(57) ABSTRACT

The present invention relates to a coated substrate comprising a substrate surface coated with a coating comprising at least one layer, wherein the at least one layer comprises titanium, aluminum and nitrogen, wherein—the content of aluminum in relation to the content of titanium in the at least one layer comprising titanium, aluminum and nitrogen satisfy Al/Ti>1 by considering only the respective concentrations in atomic percentage of aluminum and titanium in the at least one layer comprising titanium, aluminum and nitrogen, and—the at least one layer comprising titanium, aluminum and nitrogen exhibits wurtzite phase of aluminum nitride and rutile phase of titanium oxide.

The present invention relates to corrosion resistant coatings which are coatings designed for providing corrosion resistance at high temperatures.

The corrosion resistance coatings according to the present invention are designed preferably providing at the same time corrosion resistance and erosion resistance at high temperatures.

The coatings provided by the present invention are especially useful for providing corrosion resistance and erosion resistance to surface of components exposed to high temperatures during application.

The term high temperatures in the context of the present invention is used for referring to temperatures in a range comprising temperature values from 500° C. to 950° C.

According to another aspect of the present invention it relates to a stainless steel or superalloy article having an oxidation, corrosion and erosion resistant coating thereon. More particularly, according to this aspect the invention relates to a high chromium containing steel article and to titanium alloys, such as the ones employed in the compressor sections of a gas turbine engine for land-based, aero gas turbines and steam turbines, and exposed to oxidising, corrosive and erosive environment at moderated to elevated service temperature, having an inventive oxidation, corrosion and erosion resistant coating thereon.

The present invention relates in particular to coatings that are especially suitable for protecting components or parts of components used in the aerospace and power generation industry. Therefore, these inventive coatings are especially suitable for being deposited on substrate materials, such as e.g. stainless steel or Ni-based, Co-based or NiCo-based superalloy materials, preferably by Physical Vapor Deposition (PVD) in order to increase the resistance against oxidation, corrosion and erosion. More particularly, the invention relates to articles and components employed in a gas turbine engine for land-based and aero gas turbines, and to steam turbine engines, and exposed to oxidising, corrosive and erosive environment at moderate to elevated service temperature, having an inventive oxidation, corrosion and erosion resistant coating thereon.

Furthermore, the present invention relates to a PVD method, particularly a cathodic arc deposition method, to apply the inventive coating to the article.

### STATE OF THE ART

There have been strong efforts to develop coatings for gas turbine components, in order to improve the corrosion and erosion resistance of the base material. Although several coating solutions for this application do exist, the current need for a further increase in performance and lifetime of turbine compressor components calls for improvements even for already well-established and widely used coating materials. Considering the development of coating systems for this application, one specific difficulty is to fulfill the requirements for the corrosion resistance of the coating and at the same time fulfill the requirements for the erosion resistance of the coating.

Industrial gas turbines are frequently operated in regions which require different protection with respect to corrosion, such as those near chemical or petrochemical plants, where various chemical species may be found in the intake air, or those at or near ocean coastlines or other saltwater environments where various sea salts may be present in the intake air, or combinations of the above, or in other applications where the inlet air contains corrosive chemical species.

Water droplet exposure can result from use of on-line water washing, fogging and evaporative cooling, or various combinations of these processes, to enhance compressor efficiency. Among the various ionic species, which reach the surface of turbine components by water droplets, are Cl⁻, Br⁻, F⁻, S₂⁻ among others. Electrochemically induced corrosion and erosion phenomena occurring at the leading edge can in turn result in cracking and even breaking of the airfoils thus bringing huge damage and economic loss to the whole engine. And finally, oxidation may occur in hot steam or in ambient at higher temperatures.

For example, stainless steel turbine compressor components, such as e.g. airfoils, of industrial gas turbines have shown susceptibility to water droplet erosion and corrosion fatigue of the airfoil surfaces. Using titanium alloys, nickel-based or cobalt-based superalloys instead of stainless steel for the components can improve the corrosion resistance, however this may not solve the water droplet erosion problem, since the metal materials are also ductile and susceptible to erosion. Furthermore a redesigning process of the turbine components would be needed due to their different metallurgical and mechanical properties. Furthermore the mentioned substrate materials may not be able to withstand the elevated temperatures occurring at later stages of an industrial gas turbine. For example, the application temperature for titanium alloys is limited to around 540° C. Compressor blades of land based gas turbines are often made of 12% chromium containing martensitic stainless steel. Chromium is the key ingredient for the corrosion resistance of stainless steels, this kind of martensitic stainless steel is designed for service in high temperature applications up to 650° C., e.g. for turbine blades. However higher temperatures occur in some parts of an industrial gas turbine. Special austenitic stainless steels and nickel-based alloys are capable of a better performance, but at much higher cost.

In aero gas turbines “hot corrosion” can occur. During combustion in the gas turbine, sulfur from the fuel reacts with sodium chloride from ingested air at elevated temperatures to form sodium sulfate. The sodium sulfate then deposits on the hot-section components, such as nozzle guide vanes and rotor blades, resulting in accelerated oxidation (or sulfidation) attack.

To prevent or reduce corrosion, erosion and oxidation of the above mentioned materials for land-based and aero gas turbines, one approach is to deposit a coating, preferably a thin-film coating, on an already well-established substrate material, e.g. on a stainless steel substrate or on a superalloy, materials which are widely used for components of industrial and aero gas turbines, such as e.g. airfoils, and design the said coating system in such a way, as to enhance the corrosion and erosion resistance of the said component. Standard substrate materials of components of industrial gas turbine compressors, e.g. blades, include stainless steel, chromium-based alloys, nickel-based alloys and titanium-based alloys. The advantage of depositing a thin-film coating on an already well-established substrate material, is that no redesigning of the components is needed, since thin-films change the dimensions of the components only on the level of micrometers. Gas turbine components are often protected by environmental or overlay coatings, which inhibit environmental damage. Different types of coatings providing protection on various components may be employed depending upon factors, such as whether the application involves exposure to air or combustion gas, and temperature exposure.

One type of coating, an anti-wear coating, is described by Uihlein et al in U.S. Pat. No. 9,427,937B2, especially for components which are subject to erosion under mechanical stress, in particular for gas turbine components. The coating consists of at least two different individual layers, which have been applied in a multiply alternating manner to a surface of a component, which is to be coated. The described coating system comprises a ceramic main layer, which is deposited directly onto the substrate, and a quasi-ductile, non-metallic intermediate layer. Thereby the quasi-ductile, non-metallic intermediate layer is configured in such a way, that the energy is withdrawn from cracks, which grow in the direction of the substrate material, by crack branching. This leads to a slow down or even stop of the formation of cracks, providing an increased life time for the so coated component. This patent focuses on the mechanical stress applied to a component of a gas turbine. However, turbines can be operated in highly corrosive environments, such as close to chemical or petrochemical plants, or in saltwater containing environments, such as at the coastline. It would therefore be desirable to have an erosion resistant as well as corrosion resistant coating applied to industrial gas turbine components.

Other authors relate to erosion and corrosion resistant coatings for airfoils. A sacrificial and erosion-resistant turbine compressor airfoil coating is described by Lipkin et al in US20100226783A1. The airfoils which are to be coated, can be made of various types of stainless steel, such as 300 series, 400 series and type 450 stainless steel, and superalloys. The coating system described in this document consists of at least two different kinds of layers, one of which is erosion resistant, the other one is corrosion resistant, whereas the sacrificial coating is more anodic with reference to the airfoil surface than the erosion resistant coating. Among the materials, noted as especially useful for the sacrificial coating, are Al, Cr, Zn, Al-based alloys, Cr-based alloys, and many more. The erosion resistant coating may comprise metal nitrides such as AlN, TiN, TiAlN, TiAlCrN, and many more. According to this patent, either the sacrificial coating or the erosion-resistant coating can be applied directly to the surface of the stainless-steel component. If the sacrificial coating is deposited directly on the surface of the stainless-steel substrate, the erosion resistant coating is deposited on the sacrificial coating, and vice versa. The sacrificial layer may be disposed as a thin film or thick film layer by any suitable application or deposition method, including chemical vapour deposition (CVD) and physical vapour deposition (PVD), for example filtered arc deposition and more typically by sputtering. The coating system provides enhanced water droplet erosion protection, enhanced galvanic and crevice corrosion resistance, and improved surface finish and antifouling capability for turbine compressor airfoil applications. However, some materials mentioned in the description of said text, such as the group of metal nitrides including AlN, TiN, TiAlN, TiAlCrN, and many more, exhibit different properties for erosion and corrosion resistance.

Besides the desire to increase the corrosion and erosion resistance, higher operating temperatures for gas turbine engines are sought in order to increase the efficiency. However, as operating temperatures increase, the durability of the components within the engine must increase accordingly.

Hazel et al disclose in EP1595977B1 a superalloy article having oxidation and corrosion resistant coating thereon. The invention particularly relates to a superalloy article, such as one employed in the turbine and compressor sections of a gas turbine engine and exposed to oxidising and corrosive environments at moderate to elevated service temperatures, having an oxidation and corrosion resistant coating thereon. Significant advances in high temperature capabilities have been achieved through the formulation of nickel- and cobalt-based superalloys. However, the components of a gas turbine engine are often simultaneously exposed to an oxidative/corrosive environment and elevated temperatures. In order to avoid damage of the turbine engine components, some of the components are protected by environmental or overlay coatings, which inhibit environmental damage. The type of coating that is chosen for a specific application or component depends on various factors such as if the application involves exposure to air or combustion gas, and temperature exposure. Turbine and compressor disks and seal elements for use at the highest operating temperatures are made of nickel-based superalloys selected for good elevated temperature toughness and fatigue resistance. These superalloys have adequate resistance to oxidation and corrosion damage, but that resistance may not be sufficient to protect these components at the operating temperatures now being reached. It has been shown that application of an aluminum nitride overlay coating to turbine disks, rotors and other components exposed to similar temperature and environment provides an effective environmentally protective coating towards ingested salts and sulfates. The overlay coating typically has good adhesion, minimal diffusion into the base substrate and limited or no debit on low fatigue properties. During engine operation and/or high temperature exposure, the overlay coating may oxidise to form a stable metal oxide on the surface of the coating providing further improved oxidation and corrosion resistance. The protective coating can also be readily reconditioned and repaired if necessary. However, the use of a superalloy article can have some disadvantages, such as the ones previously mentioned.

Corrosion processes on metallic surfaces can be very complex. Considering turbines, particularly industrial gas turbines, reactions with Cl⁻ and S⁻ are the ionic species, which predominantly influence the corrosion resistance of metallic surfaces. Reactions of said kind are also depending on and varying with the humidity. Besides that, the kinetics of said chemical reactions is also highly dependent on the temperature. If a coating is to be applied in order to increase the corrosion resistance, all of these processes have to be taken into account. Applying an erosion resistant coating to a metal substrate could otherwise lead to increased erosion resistance but could be disadvantageous for the corrosion resistance of the so coated substrate material.

### Problem to be Solved

Diffusion processes are boosted by chemical processes and elevated temperatures, and often driven by specific elements comprised in the substrate material, which is the case for e.g. chromium (Cr) and nickel (Ni) comprising substrates.

However by providing an interface which has a more negative reduction electrode potential than the substrate material, corrosion processes are reduced and diffusion processes are slowed down. Particularly advantageous is the use of PVD for elements which additionally have a high melting point. This is due to the fact that high melting point materials usually form amorphous phases when the metallic vapour is condensing at the substrate surface during the deposition. Another advantage of using PVD, especially cathodic arc deposition to produce said coating, is that the amount of droplets in the coating is decreased in comparison to other low melting point materials. The coating generated accordingly, is therefore denser and shows less defects than other state of the art coatings, which leads to a suppression of corrosion processes.

The present invention aims to provide a coating system for a stainless steel, titanium or titanium aluminide article, and for cobalt-based, nickel-based or iron based superalloys, particularly for gas turbine, steam turbine and aero turbine components, which shows enhanced corrosion and erosion resistance compared to state of the art coatings at moderate to elevated service temperatures, and which is deposited by a physical vapour deposition (PVD) method, particularly by cathodic arc deposition.

Another aim of the present invention is to disclose a physical vapour deposition (PVD) method, particularly a cathodic arc deposition method, to deposit the inventive coating system on a substrate.

### Solution of the Problem According to the Present Invention—Description of the Present Invention

The problem of the present invention is solved by providing a substrate according to claim 1 or claim 5. Such coating can be realized with a method according to independent claim 7. The dependent claims represent further inventive and preferred embodiments.

The inventors found, that providing a dedicated chemical composition and phase composition of the coating can reduce corrosion as well as diffusion processes. Particularly advantageous is the use of PVD to synthesize coatings with a dedicated phase composition, which allow to suppress diffusion and oxidation processes while at the same time keeping the excellent mechanical properties of high hardness and Young's modulus.

The present invention discloses an inventive coating system for enhanced corrosion and erosion resistance of gas turbine engine components at moderate to elevated service temperatures, whereas these components are made of e.g. stainless steel or superalloys. The inventive coating system comprises a well-defined chemical composition of elements and phase compositions, which results in a suppression of diffusion processes and in reduced oxidation. It could be shown in various standardised corrosion tests, that the inventive coating system exhibits an enhanced corrosion resistance compared to previous coating systems which are known from the state of the art. Furthermore, the inventive coating system also shows improved erosion resistance in various standardised tests.

The present invention furthermore relates to a physical vapour deposition (PVD) method, particularly to a cathodic arc deposition method, for depositing an inventive coating system.

The objective of the present invention is attained by providing a coating system on a substrate, wherein the coating system comprises a layer which is either a monolayer or a multilayer system. The layer, if monolayer, comprising titanium aluminum nitride or consisting of aluminum titanium nitride, or the layer, if multilayer, comprising at least one layer comprising or consisting of titanium aluminum nitride (hereafter this layer comprising or consisting of titanium aluminum nitride will be also referred to as TiAlN layer), wherein the layer (monolayer or multilayer) is deposited either directly on the substrate, or on a metallic interlayer.

As mentioned above the metallic interlayer is optional and should be deposited directly on the substrate material. The optional metallic interlayer is preferably deposited containing or consisting of niobium (Nb), chromium (Cr), zirconium (Zr), hafnium (Hf) or molybdenum (Mo), or any combinations thereof. However, the element composition of the metallic interlayer is not limited to these directly above-mentioned elements but designed containing or consisting of other metallic elements.

The monolayer or the at least one layer of the multilayer comprising or consisting of TiAlN is deposited preferably forming the outermost surface of the coating (i.e. the TiAlN layer is preferably deposited as top layer of the coating system).

Surprisingly, depositing coatings comprising a titanium aluminum nitride layer (TiAlN layer) according to the present invention, with a chemical composition, for which the ratio of aluminum (Al) to titanium (Ti) in the titanium aluminum nitride (TiAlN) is higher than one, Al/Ti>1, it was possible to attain a strongly enhanced corrosion and erosion resistance. Further investigations of the synthesized coatings, in order to elucidate the reason for the improved coating properties, showed the presence of the aluminum nitride wurtzite phase (w-AlN) in the deposited TiAlN layer.

Thus, according to the present invention, the titanium aluminum nitride layer (the TiAlN layer) contains an aluminum nitride wurtzite phase (w-AlN).

In order to synthesise a titanium aluminum nitride (TiAlN) coating comprising a wurtzite phase (w-AlN), different types of aluminum titanium (Al—Ti) compound targets with various chemical compositions were used. Several compound targets with an aluminum (Al) to titanium (Ti) ratio Al/Ti of 60/40, 67/33, 70/30, 80/20 and 90/10 were tested. In all cases, an excellent improvement of corrosion resistance could be observed.

### DESCRIPTION OF FIGURES

FIG. 1 XRD diffractogram of a state of the art TiAlN coating deposited by cathodic arc from a target with a ratio of Al:Ti of 50:50, substrate temperature T=350° C.

FIG. 2 XRD diffractogram of a state of the art TiAlN coating deposited by cathodic arc from a target with a ratio of Al:Ti of 50:50, substrate temperature T=480° C.

FIG. 3 XRD diffractogram of an embodiment of an inventive TiAlN coating deposited by cathodic arc from a target with a ratio of Al:Ti of 60:40, substrate temperature T=350° C.

FIG. 4 XRD diffractogram of an embodiment of an inventive TiAlN coating deposited by cathodic arc from a target with a ratio of Al:Ti of 60:40, substrate temperature T=480° C.

FIG. 5 Solid Particle Erosion (SPE) results of state of the art and two embodiments of the inventive coating on Inconel718 at impact angles of 20° and 90°

FIG. 6 Hot Corrosion Resistance test performed at a temperature between 730 and 735° C. (e.g. 732° C.), of one embodiment of an inventive coating system deposited on an Inconel718 substrate, with a substrate temperature of T=350° C.

FIG. 7 Rotating beam fatigue test results of an embodiment of the inventive coating, deposited by cathodic arc from a target with Al:Ti ratio of 60:40, substrate temperature 480° C.

FIG. 8 Schematic illustration of a cathodic arc evaporation set-up to deposit the inventive coating on a substrate sample

FIG. 9 Schematic representation of one embodiment of the inventive coating system

FIG. 10 XRD diffractogram for a TiAlN coating on a 1.4938 stainless steel substrate

Subsequently, some embodiments of the present invention will be described by way of example, which is meant to be merely illustrative and therefore non limiting. In order to show the improvement of the corrosion resistance of the inventive coating, the inventive coating as well as several state of the art coatings were tested, and the results of said test are described in the following.

A state of the art titanium-aluminum (Ti—Al) target with Aluminum (Al) to Titanium (Ti) ratio of Al/Ti=50/50 was provided in order to deposit a thin-film coating on an Inconel substrate using cathodic arc evaporation. This was done for two different substrate temperatures, T=350° C. and T=480° C. The nitrogen gas pressure was set to 3.2 3.2e-2 mbar. For a deposition temperature of T=350° C., a composition of the deposited coating of titanium (Ti) is 24.2 at %, aluminum (Al) is 20.7 at % and nitrogen (N) is 55.2 at % measured by Energy Dispersive X-Ray (EDX) Analysis. For a deposition temperature of T=480° C., a composition of the deposited coating of titanium (Ti) is 23.2 at %, aluminum (Al) is 20.2 at % and nitrogen (N) is 56.2 at % measured by EDX. It can be seen, that the state of the art coatings have approximately the same compositions, independent of the deposition temperature.

The properties of the state of the art titanium aluminum nitride (TiAlN) coating evaporated from a titanium-aluminum (Ti—Al) target with an aluminum (Al) to titanium (Ti) ratio of Al/Ti=50/50, and deposited at T=350° C. were further investigated. Said coating exhibits a thickness of 14 μm, a stress on a steel substrate of −1.6 GPa, an Indentation Hardness H_{IT} of 29±2 GPa, an Youngs modulus by indentation E_{IT} of 390±13 GPa, a surface roughness of Rₐ=0.26 μm and R_{z}=3.14 μm and a Critical Normal Load Lc2 of 48 N.

The properties of the state of the art titanium aluminum nitride (TiAlN) coating evaporated from a titanium-aluminum (Ti—Al) target with an aluminum (Al) to titanium (Ti) ratio of Al/Ti=50/50, and deposited at T=480° C. were further investigated. Said coating exhibits a thickness of 15 μm, a stress on a steel substrate of −1.6 GPa, an Indentation Hardness H_{IT} of 32±2 GPa, an Youngs modulus by indentation E_{IT} of 383±20 GPa, a surface roughness of Rₐ=0.19 μm and R_{z}=2.62 μm and a Critical Normal Load Lc2 of 62 N.

In one embodiment of the inventive coating, a titanium-aluminum (Ti—Al) target with aluminum (Al) to titanium (Ti) ratio of Al/Ti=60/40 was provided. As for the above-mentioned state of the art coatings, the deposition of the inventive coating on an Inconel substrate was performed for two different substrate temperatures, T=350° C. and T=480° C. The nitrogen gas pressure was set to 3.2 Pa. For a deposition temperature of T=350° C., a composition of the deposited coating of titanium (Ti) is 18.7 at %, aluminum (Al) is 25.9 at % and nitrogen (N) is 55.4 at % was measured by EDX. Fora deposition temperature of T=480° C., a composition of the deposited coating of titanium (Ti) is 18.5 at %, aluminum (Al) is 25.9 at % and nitrogen (N) is 55.6 at % measured by EDX. It can be seen, that the inventive coatings have approximately the same compositions, independent of the deposition temperature.

The properties of one embodiment of the inventive titanium aluminum nitride (TiAlN) coating evaporated from a titanium-aluminum (Ti—Al) target with an aluminum (Al) to titanium (Ti) ratio of Al/Ti=60/40, and deposited at T=350° C. were further investigated. Said coating exhibits a thickness of 13 μm, a stress on a steel substrate of −0.8 GPa, an Indentation Hardness H_{IT} of 33±1 GPa, an Youngs modulus by indentation Err of 362±5 GPa, a surface roughness of Rₐ=0.25 μm and R_{z}=3.13 μm and a Critical Normal Load Lc2 of 37 N.

The properties of another embodiment of the inventive titanium aluminum nitride (TiAlN) coating evaporated from a titanium-aluminum (Ti—Al) target with an aluminum (Al) to titanium (Ti) ratio of Al/Ti=60/40, and deposited at T=480° C. were further investigated. Said coating exhibits a thickness of 12 μm, a stress on a steel substrate of −1.5 GPa, an Indentation Hardness H_{IT} of 34±1 GPa, an Youngs modulus by indentation E_{IT} of 331±8 GPa, a surface roughness of Rₐ=0.24 μm and R_{z}=3.68 μm and a Critical Normal Load Lc2 of 43 N.

A comparison of the above described properties of the embodiments of the inventive coatings and the properties of the tested state of the art coatings, show approximately similar properties.

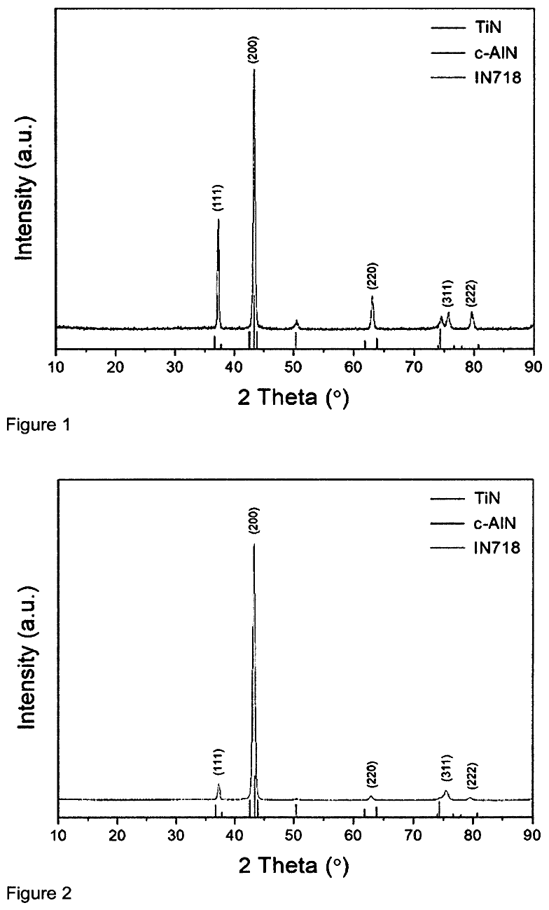

An XRD phase analysis was performed on the four previously described coatings. Looking at FIGS. 1, 2, 3 and 4, it can be seen that both state of the art coatings, using a titanium-aluminum (Ti—Al) target with an aluminum (Al) to titanium (Ti) ratio of Al/Ti=50/50, and deposited at substrate temperatures of T=350° C. and T=480° C. show only cubic phase. In contrast both embodiments of the inventive coating, using a titanium-aluminum (Ti—Al) target with an aluminum (Al) to titanium (Ti) ratio of Al/Ti=60/40, and deposited at substrate temperatures of T=350° C. and T=480° C. show cubic and hexagonal aluminum nitride (AlN) phases. The difference can also be seen in the Cross Sectional Analysis of the four tested coatings. Both embodiments of the inventive coating, using a titanium-aluminum (Ti—Al) target with an aluminum (Al) to titanium (Ti) ratio of Al/Ti=60/40, and deposited at substrate temperatures of T=350° C. and T=480° C. show less columnar grains, than the state of the art coatings, using a titanium-aluminum (Ti—Al) target with an aluminum (Al) to titanium (Ti) ratio of Al/Ti=50/50, and deposited at substrate temperatures of T=350° C. and T=480° C.

After annealing the XRD phase analysis was repeated. In addition to the cubic and wurtzite AlN phase the anatase and rutile TiO2 phases were formed. Furthermore, an aluminium oxide was formed, which could not be detected in XRD, but was detected by EDX in Cross Sectional Analysis.

Furthermore the oxidation resistance of the two state of the art coatings as well as the oxidation resistance of the two above described embodiments of the inventive coating system was tested at T=650° C., 677° C., 732° C. The oxide scale thickness was measured to be approximately 300 nm after 24 h and no significant increase of the oxide scale could be detected after 200 h.

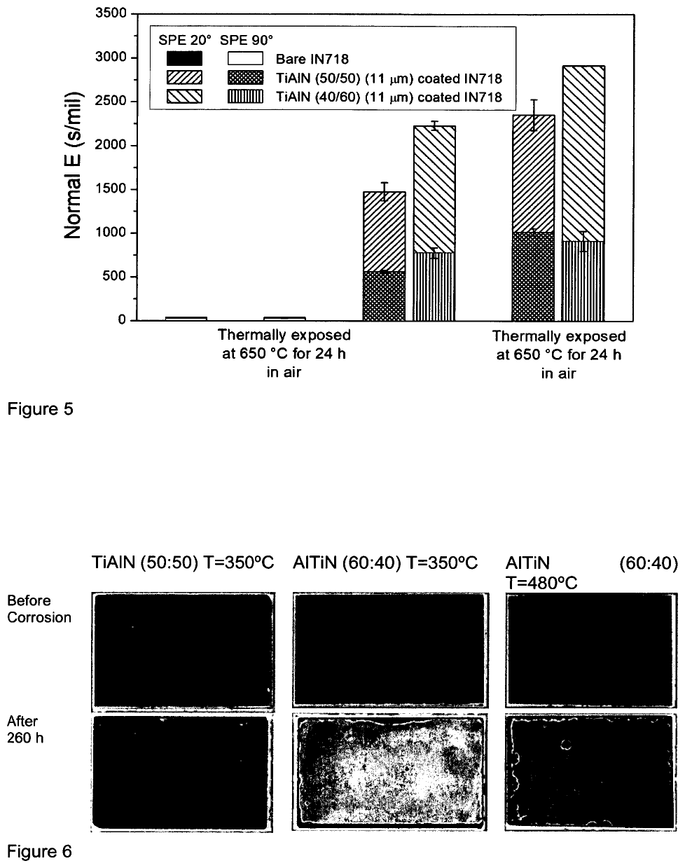

The erosion resistance of two embodiments of the inventive coating system was compared with the erosion resistance of a state of the art coating and uncoated substrate materials using a Solid Particle Erosion (SPE) test. Therefore four different samples were tested at impact angles of 20° and 90° using corundum abrasive particles (approximately 50 μm) with a nozzle to sample distance of 90 mm, a speed of 90 m/s and an abrasive feed rate of 350 g/min. The erosion resistance of the SPE tested samples is shown in FIG. 5. It can be seen, that the erosion resistance of the tested inventive aluminum titanium nitride (AlTiN 40/60) coating is higher than the erosion resistance of the tested state of the art aluminum titanium nitride (AlTiN 50/50) coating.

Furthermore, the corrosion resistance of an embodiment of the inventive coating system, directly after deposition and after annealing, was compared to the corrosion resistance of equivalently treated bare Inconel718 and to an equivalently treated Inconel718 substrate coated with a state of the art coating. The state of the art coating was deposited at a substrate temperature of T=350° C. Two embodiments of the inventive coatings were deposited at substrate temperatures T=350° C. and T=480° C. A Neutral Salt Spray Test (NSST) according to DIN EN ISO 9227 was carried out on the samples. After 432 h of NSST the bare Inconel718 substrate shows no corrosion, the Inconel718 substrate coated with a state of the art titanium aluminum nitride (TiAlN) based coating, deposited at T=350° C. also shows no corrosion after 432 h. Furthermore, the Inconel718 substrate coated with a state of the art titanium aluminum nitride (TiAlN) based coating, and deposited at T=350° C., which was thermally exposed to a temperature of T=650° C. for 24 h, shows no corrosion (Ri0). After 432 h of NSST the bare Inconel718 substrate shows no corrosion, while the Inconel718 substrate coated with a state of the art titanium aluminum nitride (TiAlN) based coating, deposited at T=480° C. shows no corrosion after 432 h. Furthermore, the Inconel718 substrate coated with a state of the art titanium aluminum nitride (TiAlN) based coating, and deposited at T=480° C., which was thermally exposed to a temperature of T=650° C. for 24 h, shows no corrosion (Ri0).

The samples were also tested in a hot corrosion test which was performed at a temperature between 730° C. and 735° C. using salt mixture of magnesium sulfate (MgSO₄) and sodium sulfate (Na₂SO₄) for 260 h. All the tested coatings were deposited on Inconel718 substrates at a substrate temperature of T=350° C. It can be seen in FIG. 6, that the hot corrosion resistance of one embodiment of an inventive aluminum titanium nitride (60:40) coating is much better than the hot corrosion resistance of a tested state of the art titanium aluminum nitride (50:50) coating.

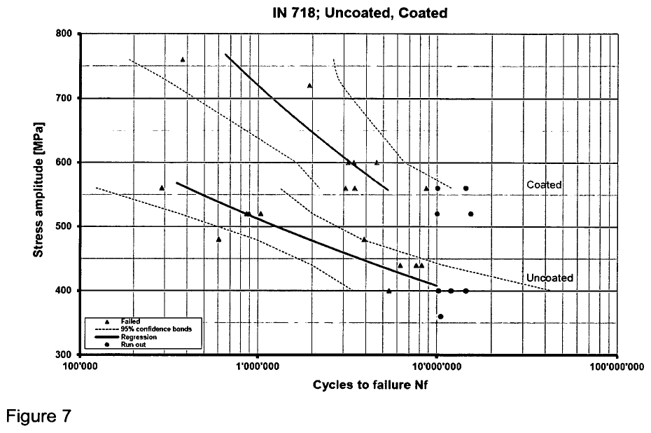

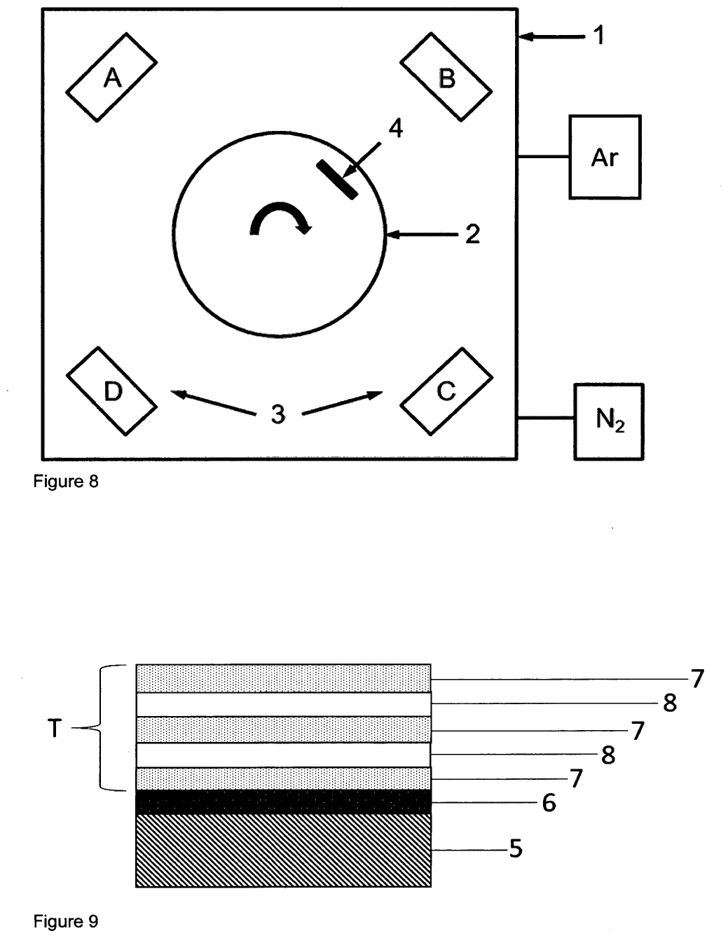

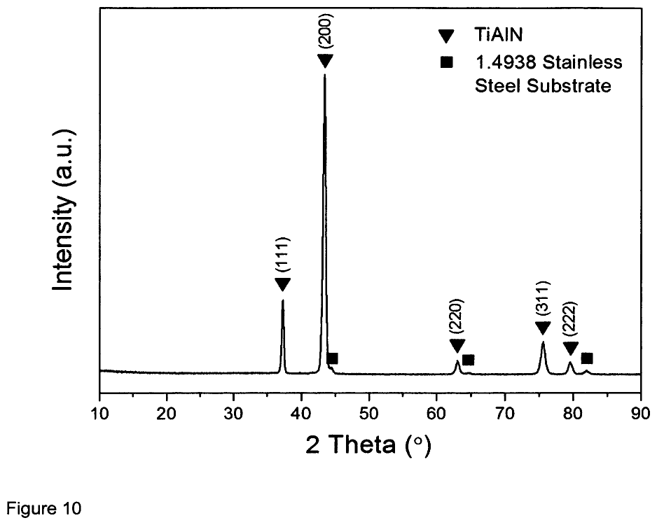

The coating was also tested in rotating beam fatigue test, as can be seen in FIG. 7. The test was performed using staircase method with a frequency of 100 Hz and a reverse stress cycle of R=−1 at room temperature. The results were evaluated according to ASTM E739 standard. No fatigue debit could be detected.

According to one aspect of the present invention, the inventive coating can be deposited using a PVD method, preferably sputtering or cathodic arc. An embodiment of applying the inventive coating system with the use of cathodic arc will be described.

The said coating system is deposited on a sample using a cathodic arc deposition method. In order to apply the inventive coating system to a sample, using the inventive coating method, a sample is placed in a vacuum coating chamber. The substrate is placed rotatable in the center of said vacuum chamber on a carousel. The inventive coating system can be deposited on the sample by using a different amount of targets functioning as cathodes, such as for example two, four, six or even more targets. The order and number of the targets can be of any desired kind. The targets are preferably mounted at the walls of the vacuum coating chamber. In order to produce the inventive coating system described in this specific embodiment, the cathodes are aluminum titanium (AlTi) targets, whereas the ratio Al/Ti>1. The target positions are to be seen as only one example of the present invention and are not limiting. In order to generate the nitride containing layers, a non-zero amount of N₂ is inserted into the vacuum chamber through the gas inlet. In this example the N₂ pressure was set to 3.2e-2 mbar. Preferably an argon (Ar) gas inlet is installed as well, in order to use argon as a work gas. In order to produce the inventive coating system, the coating temperature is chosen within a range between 200-500° C. Magnets are located behind the targets, and the magnetic field can be adjusted in order to influence the coating. Shutters can be installed in front of the targets to allow different coating layers, but are not compulsory.

The above described examples of the inventive coating system and the methods to deposit the inventive coating system are however not limiting. The ratio of aluminum (Al) to titanium (Ti) found in the target could as well be chosen differently. A ratio within the range of Al: 60 at %, Ti: 40 at % and Al: 90 at %, Ti: 10 at % leads to a cubic titanium aluminum nitride (TiAlN) and hexagonal wurtzite aluminum nitride (w-AlN) formation, for this two-phase-coating preferably a ratio of Al: 80 at %, Ti: 20 at % is chosen. Choosing the composition in order to form a hexagonal wurtzite aluminum nitride (w-AlN) leads to a slight reduction of the hardness and elastic modulus of the coating, but to increased corrosion and oxidation resistance compared to the cubic phase, which is commonly formed for nitrides.

The inventors found another surprising fact: A coating system which comprises a metallic interlayer and a top layer, which can consist of either a monolayer or a multilayer system of titanium aluminum nitride (TiAlN) exhibits as well improved corrosion resistance. It could be shown in various standardized corrosion tests, that the coating exhibits an enhanced corrosion resistance compared to previous coating systems which are known from the state of the art. Furthermore the coating system also shows improved erosion resistance in various standardized tests.

According to this, a coating system on a substrate is provided, consisting of one individual interlayer containing niobium (Nb), chromium (Cr), zirconium (Zr), hafnium (Hf) or molybdenum (Mo), or any combinations thereof, which are deposited directly on the substrate material, and a top layer (T) which is either a monolayer or a multilayer system of titanium aluminum nitride (TiAlN) layers, which can exhibit different ratios of titanium (Ti) to aluminum (Al) to nitrogen (N). One version of the coating system is shown in FIG. 9, where a niobium interlayer (6) is deposited on the substrate (5), followed by titanium aluminum nitride (TiAlN) layers with different compositions, which are arranged in an alternating way. However this is only one example and not limiting.

Turning now back to the first aspect of the present based on an individual interlayer containing niobium (Nb), chromium (Cr), zirconium (Zr), hafnium (Hf) or molybdenum (Mo), or any combinations thereof, which are deposited directly on the substrate material, and a top layer (T) which is either a monolayer or a multilayer system of titanium aluminum nitride (TiAlN) layers, which can exhibit different ratios of titanium (Ti) to aluminum (Al) to nitrogen (N).

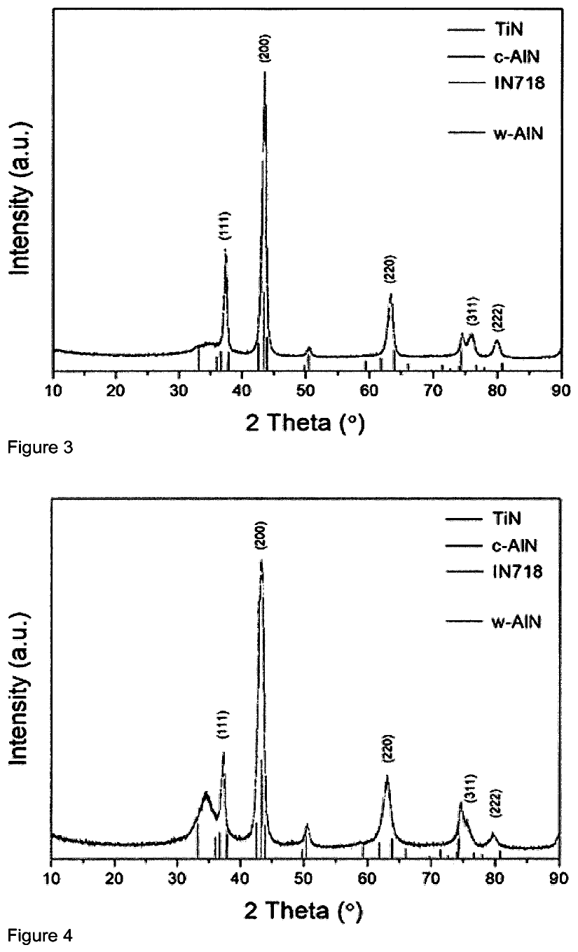

If for example a titanium aluminum nitride (TiAlN) monolayer with a certain composition is used as a top layer (T), the coating thickness can range from 1 μm to 50 μm and is preferably chosen to be between 1 μm and 25 μm. The titanium aluminum nitride (TiAlN) layer shows a cubic crystal structure, as can be seen in FIG. 3, and a lattice constant of a=4.171 Å. The composition is preferably chosen to be Ti: 23±2 at %, Al: 22±2 at %, N: 55±4 at %, but is not limited to this specific composition. The indentation hardness was measured to be 30±2 GPa. The indentation modulus was measured to be 385±12 GPa. The coating hardness was measured using an instrumented indentation test with a Vickers Indenter and a maximum measuring force of 100 mN inside a calo grind. The listed results are average values of 20 single measurements. The hardness values were evaluated according to the Oliver and Pharr method. The indentation depth is less than 10% of the coating thickness to minimise substrate interference.

The above described example is however not limiting. The ratio of aluminum (Al) to titanium (Ti) could as well be chosen differently. A ratio within the range of Al: 70 at %, Ti: 30 at % and Al: 90 at %, Ti: 10 at % leads to a two phase structure consisting of cubic NaCl and hexagonal Wurtzite structure, i.e. to the formation of Wurtzite AlN (w-AlN). Preferably a ratio of Al: 80 at %, Ti: 20 at % is chosen. Choosing the composition in order to form the hexagonal Wurtzite phase leads to a slight reduction of the hardness and elastic modulus of the coating, but to increased corrosion and oxidation resistance compared to the cubic phase, which is commonly formed for nitrides. Layers produced accordingly, can be applied either as a monolayer, as one or more layers in a multilayer system, or the multilayer system can comprise only layers with compositions of aluminum (Al) to titanium (Ti) which exhibit w-AlN.

Titanium aluminum nitride (TiAlN) exhibits excellent solid particle erosion resistance and water droplet erosion resistance. However, when tested in a neutral salt spray test (NSST) according to DIN EN ISO 9227, after 24 h red rust was observed at the 1.4313 stainless steel substrate which was coated with a titanium aluminum nitride (TiAlN) monolayer.

For some applications a multilayer system (T) can be beneficial, in order to find a balance between good erosion resistance and good corrosion resistance. The coating system can for example be deposited as shown in FIG. 2, where the top layer (T) consists of several titanium aluminum nitride (TiAlN) layers, with layers (7) and (8) having different ratios of titanium (Ti) to aluminum (Al) to nitrogen (N). This is one example of how the coating system can be designed, but is not limiting. The ratios of titanium (Ti) to aluminum (Al) to nitrogen (N) could as well be different for every single layer of the multilayer system of the top layer (T).

The substrate (5) materials to be coated include but are not limited to stainless steel, superalloys and titanium alloys. The coating is especially suitable to be applied on substrate materials such as high-chromium (9-18 wt %) containing steel, e.g. 1.4313 stainless steel, 1.4938 stainless steel, titanium, titanium alloy, intermetallics such as titanium aluminides, Inconel as well as nickel-based, cobalt-based and iron-based superalloys.

As mentioned before, corrosion processes on metallic surfaces can be very complex. Reactions can be influenced by the presence of various ionic species, humidity, temperature, and other factors. One possibility to improve the corrosion resistance, is to apply a so called sacrificial coating. Whether a metal is suitable to be used as a sacrificial coating in a specific application, depends on the absolute difference between the standard potentials of the metallic interlayer, which is to be used as a sacrificial coating, and the substrate material. In order to determine the standard potential of a metal, the electrode potential of said metal is compared with the standard hydrogen electrode, and is called the standard electrode potential E⁰. This can be done for all the metals. Potentials between metals are determined by taking the absolute difference between their standard potentials. A metal with a more negative potential has a higher tendency to dissolve and thus corrode, than a metal with a less negative potential, although kinetic factors may intervene. If the potential of a metal is less than the hydrogen potential, reduction rather than oxidation takes place. Metals which correspond to relatively lower standard potentials E⁰ are called active metals, and metals which correspond to relatively higher standard potential or less negative potentials are called noble metals. For example considering two metals, such as zinc (Zn) and aluminum (Al), aluminum (Al) is more active than zinc (Zn) since E⁰_{Al}=−1.66 V, E⁰_{Zn}=−0.763 V.

In order to improve the adhesion between the substrate (5) and the titanium aluminum nitride (TiAlN) coating, as well as the corrosion resistance of the so coated substrate, a metallic interface (6) containing niobium (Nb), chromium (Cr), zirconium (Zr), hafnium (Hf) or molybdenum (Mo), preferably consisting of said metals, or any combinations thereof, is deposited directly on the substrate. The said materials are metallic materials, which are sacrificial coatings. For a sacrificial coating only materials which exhibit a higher electronegativity than the substrate materials can be used. Checking the standard electrode potentials E⁰ of niobium (Nb), chromium (Cr), zircon (Zr), hafnium (Hf) or molybdenum (Mo) with respect to the standard hydrogen electrode, leads to the conclusion that these materials can be used as a sacrificial layer for the above mentioned substrate materials. The metallic interface (6) is thus adjusted to the substrate material in order to minimise the corrosion potential between the substrate material and the titanium aluminum nitride (TiAlN) coating, thus enhancing the corrosion resistance of the coating system. If for example a nickel based alloy (E⁰_{Ni}=−0.257 V) or cobalt based alloy (E⁰_{Co}=−0.28 V) is to be protected against diffusion and corrosion, a sacrificial layer consisting of or containing aluminum (Al) with E⁰_{Al}=−1.662 V is commonly used. However the materials used in this specific application have to exhibit a high melting point, to ensure a certain hardness, since materials with a high melting point are often denser than materials with a lower melting point. For this application, materials exhibiting amorphous phases, and are microcrystalline and glassy, are preferred. A columnar structure of the material is not desired, since this would lead to a decreased hardness. Unfortunately aluminum has a melting point of only 660° C. One possible solution is the use of a sacrificial layer consisting of or containing hafnium (Hf) with E⁰_{Hf}=−1.55 V. As can be seen the reduction potentials E⁰ with respect to the standard hydrogen electrode of hafnium (Hf) is slightly lower than that of aluminum (Al). However hafnium has a high melting point of 2231° C., and thus leads to the desired dense structure, and at the same time provides good diffusion and corrosion resistance for a substrate material, such as e.g. titanium. The same effect is seen when using niobium (Nb), chromium (Cr), zirconium (Zr) or molybdenum (Mo) as an interlayer. Depending on the reduction potentials E⁰ with respect to the standard hydrogen electrode of the substrate material, the material used for the interface is adjusted.

An example will be described by way of example, which is meant to be merely illustrative and therefore non limiting.

According to one embodiment of the example a 1.4313 stainless steel substrate was coated with a coating system. A niobium (Nb) interlayer was deposited directly on the surface, followed by a titanium aluminum nitride (TiAlN) monolayer with a Ti:Al ratio of 1:2, which was deposited directly on the niobium (Nb) interface. The overall thickness of the coating system was chosen to be 6 μm, whereas the thickness of the niobium (Nb) interlayer was 1 μm and the thickness of the titanium aluminum nitride (TiAlN) top layer was 5 μm. The coating temperature was set to 350° C. A set-up providing 4 sources was used to coat said sample with said coating system, two of them consisting of niobium (Nb), two consisting of titanium aluminum (TiAl). The so coated sample was tested for corrosion resistance in a neutral salt spray test (NSST) according to DIN EN ISO 9227.

Another example uses a chromium (Cr) interlayer and a titanium aluminum nitride (TiAlN) monolayer with a Ti:Al ratio of 1:1 on top. A 1.4313 stainless steel substrate was coated with the said example of a coating system, whereas the coating was applied at a temperature of 300° C., and exhibited a thickness of 16 μm. The sample was coated using 6 sources. The so coated sample was tested for corrosion resistance in a neutral salt spray test (NSST) according to DIN EN ISO 9227.

One embodiment of a method to deposit a coating on a substrate, is to use an interface consisting of niobium (Nb). Optionally a flow of one or more inert gases (e.g. argon (Ar)) can be introduced into the vacuum coating chamber as work gas. The metallic interface, in this case niobium (Nb), is preferentially applied using an argon (Ar) work gas. For the deposition of the coating system in a PVD vacuum chamber, depending on the desired layers to be coated, either one or more targets comprising aluminum (Al), titanium (Ti) or niobium (Nb), or titanium aluminum (TiAl) targets with various ratios of aluminum (Al) to titanium (Ti) in the solid phase can be used as a material source for supplying the metallic base materials needed to generate the layers of the coating system. For example, aluminum (Al) and titanium (Ti) targets, or titanium aluminum (TiAl) targets with different compositions or ratios of aluminum (Al) to titanium (Ti) are needed for the formation of an titanium aluminum nitride (TiAlN) multilayer system. However for the formation of some layers, such as titanium aluminum nitride (TiAlN) layers, an additional gas flow is required. A nitrogen (N₂) gas flow is introduced to the vacuum chamber to be used as reactive gas to form titanium aluminum nitride (TiAlN).

The one or more targets can be operated as cathodes in order to deposit the target material onto the substrate, for example by using arc vaporisation techniques or by using any sputtering technique.

As mentioned before, nitride coatings can be generated by operating the targets in a reactive atmosphere comprising nitrogen. The amount of nitrogen which is incorporated in the titanium aluminum nitride (TiAlN) layer can be varied by changing the amount of nitrogen in the vacuum coating chamber, more precisely the nitrogen gas flow.

In the context of the present solution the ‘one or more targets comprising aluminum (Al), titanium (Ti), niobium (Nb), zirconium (Zr), hafnium (Hf), molybdenum (Mo) or aluminum titanium (AITO targets with various ratios of aluminum (Al) to titanium (Ti)’ mentioned above, are targets comprising said metals as main components. Preferably the said targets are targets consisting of the above listed metals or any combinations thereof, which can comprise traces of impurities. To deposit a titanium aluminum nitride (TiAlN) coating with a certain titanium (Ti) to aluminum (Al) ratio of u:v, the solid target is manufactured in such a way as to exhibit a titanium (Ti) to aluminum (Al) ratio of u:v.

In one embodiment of the present solution, an multilayer coating system as shown in FIG. 9, is deposited on a substrate (4) using an arc deposition method with equipment as shown in FIG. 8. The coating system shown in FIG. 9, as well as the arc deposition method described below, are to be seen as only one example but are not limited to this variant. Generally a titanium aluminum nitride (TiAlN) layer can have different compositions TiₓAl₁₋ₓN_{y} with x ∈ [0.05, 0.95] and y=1±0.3. As shown in FIG. 2, a TiAlN (7) layer with composition Tiₓ₁Al₁₋ₓ₁N_{y1} is deposited on a niobium (Nb) interlayer (6). Another TiAlN (8) layer with composition Tiₓ₂Al₁₋ₓ₂N_{y2} is deposited on the TiAlN (7) layer with composition Tiₓ₁Al₁₋ₓ₁N_{y1}. The titanium aluminum nitride (TiAlN) layers with different compositions Tiₓ₁Al₁₋ₓ₁N_{y1} and Tiₓ₂Al₁₋ₓ₂N_{y2} are arranged in an alternating way.

As shown in FIG. 8, the said coating system is applied to a sample (4) using an arc deposition method. In order to apply the coating system to a sample (4), using the coating method, a sample (4) is placed in a vacuum coating chamber (1). The sample (4) is placed rotatable in the center of said vacuum chamber on a carousel (2). The coating system can be deposited on the sample (4) by using a different amount of targets functioning as cathodes, such as for example two, four or even more targets. The set-up shown in this particular example (FIG. 1) contains four targets, all of them set up in a way as to work as cathodes. As can be seen in FIG. 1 the targets are mounted at the walls of the vacuum coating chamber. In order to produce the coating system described in this specific embodiment, cathodes A and B are targets comprising niobium (Nb) as main component, and cathodes C and D are targets comprising titanium aluminum (TiAl) as main component. First the samples are pretreated in order to prepare them for the coating. The metallic interlayer, in this case niobium (Nb) is then deposited on the sample by switching on the niobium targets (Nb) and using argon (Ar) as a work gas. Therefore an argon (Ar) pressure of 10e-2 mbar is used. In order to generate the nitrogen (N) containing layers, a non-zero amount of N₂ is inserted into the vacuum chamber through the gas inlet, the argon gas flow is sustained during this step of the process. Once the N₂ pressure is stabilised, the titanium aluminum (TiAl) targets are switched on and the argon (Ar) is removed from the chamber. In this example the N₂ pressure was set to 3.2e-2 mbar. In order to produce the coating system, the coating temperature is chosen within a range of 300-600° C. In this example, shutters (3) are installed in front of the targets (A, B, C, D), to allow coating different layers. However coatings of said kind can also be deposited if no shutters are installed. The coating thickness of the individual layers of the multilayer system described herein can be chosen to be at most 5 μm. If the coating is applied according to the above described method, shown in FIG. 8, a gradient is seen.

A coated substrate was disclosed comprising a substrate surface coated with a coating comprising at least one layer, wherein the at least one layer comprises titanium, aluminum and nitrogen, and wherein:
the content of aluminum in relation to the content of titanium in the at least one layer comprising titanium, aluminum and nitrogen satisfy Al/Ti>1 by considering only the respective concentrations in atomic percentage of aluminum and titanium in the at least one layer comprising titanium, aluminum and nitrogen, and
the at least one layer comprising titanium, aluminum and nitrogen exhibits wurtzite phase of aluminum nitride and rutile phase of titanium oxide.

Preferably the substrate material is stainless steel or a Ni-based, or Co-based or NiCo-based superalloy material.

Preferably the coated substrate is a part of a component or is a part of an article or is a component or is an article used in the aerospace or power generation industry.

Preferably the coated surface is intended to be exposed to air at temperatures in a range comprising temperature values from 500° C. to 950° C.

A coated substrate is disclosed comprising a substrate surface coated with a coating comprising at least one layer, wherein the at least one layer comprises titanium, aluminum and nitrogen, and wherein:
the content of aluminum in relation to the content of titanium in the at least one layer comprising titanium, aluminum and nitrogen satisfy Al/Ti>1 by considering only the respective concentrations in atomic percentage of aluminum and titanium in the at least one layer comprising titanium, aluminum and nitrogen, and
the at least one layer comprising titanium, aluminum and nitrogen exhibits wurtzite phase of aluminum nitride, and
the substrate is a part of a component or is a part of an article or is a component or is an article used in the aerospace or power generation industry, wherein the substrate material is preferably stainless steel or a Ni-based, or Co-based or NiCo-based superalloy material.

For the coated substrate the following ratios may be realized: 54/46≤Al/Ti≤80/20, preferably 54/46≤Al/Ti≤70/30.

A method is disclosed for producing a coated substrate according to any of the previous claims 1 to 4, characterized in that the at least one layer comprising titanium, aluminum and nitrogen is produced by using a process including at least following process steps a) and b):
a) deposition of a layer comprising titanium aluminum and nitrogen on at least one surface of the substrate, wherein said layer comprising titanium aluminum and nitrogen is deposited exhibiting wurzite phase of aluminum nitride and having content of aluminum in relation to the content of titanium satisfying Al/Ti>1, if considering only the respective concentrations of aluminum and titanium in atomic percentage and,
b) subjecting the substrate coated as indicated in process step a) to a process in which rutile phase of titanium oxide is formed.

The process step a) can be conducted by using physical vapor deposition techniques for the deposition of the layer comprising titanium aluminum and nitrogen and the process step b) can be conducted including exposition of at least a part of the substrate coated as indicated in process step a) to temperatures between 500 C and 950° C.

The physical vapor deposition process may be a reactive cathodic arc evaporation process.

A target composed of aluminum and titanium and having element composition satisfying Al/Ti>1 in atomic percentage is used as material source and nitrogen gas is used as reactive gas during deposition of the layer comprising titanium aluminum and nitrogen.

At least one target may have the composition: Al 60 at. % and Ti 40 at. %

References

| | |
|---|---|
| 1 | Coating Chamber |
| 2 | Carousel |
| 3 | Shutter |
| 4 | Sample |
| A, B | Al Cathodes |
| C, D | TiAl Cathodes |
| N₂ | Reactive Gas |
| Ar | Working Gas |
| 5 | Substrate |
| 6 | Nb Interlayer |
| 7 | Tiₓ₁Al₁₋ₓ₁N_{y1} |
| 8 | Tiₓ₂Al₁₋ₓ₂N_{y2} |
| T | Top Layer |

1. A coated substrate comprising:
a substrate surface coated with a coating comprising at least one layer, wherein the at least one layer comprises titanium, aluminum and nitrogen, and
a content of aluminum in relation to a content of titanium in the at least one layer comprising titanium, aluminum and nitrogen satisfies Al/Ti>1 by considering only respective concentrations in atomic percentage of aluminum and titanium in the at least one layer comprising titanium, aluminum and nitrogen, and
the at least one layer comprising titanium, aluminum and nitrogen exhibits wurtzite phase of aluminum nitride and rutile phase of titanium oxide.

2. The coated substrate according to claim 1,
wherein the substrate material is stainless steel or a Ni-based, or Co-based or NiCo-based superalloy material.

3. The coated substrate according to claim 2, wherein the substrate is a part of a component or is a part of an article or is a component or is an article used in the aerospace or power generation industry.

4. The coated substrate according to claim 3, wherein the coated surface is intended to be exposed to air at temperatures in a range from 500° C. to 950° C.

5. A coated substrate comprising:
a substrate surface coated with a coating comprising at least one layer, wherein the at least one layer comprises titanium, aluminum and nitrogen, and
a content of aluminum in relation to a content of titanium in the at least one layer comprising titanium, aluminum and nitrogen satisfies Al/Ti>1 by considering only respective concentrations in atomic percentage of aluminum and titanium in the at least one layer comprising titanium, aluminum and nitrogen, and
the at least one layer comprising titanium, aluminum and nitrogen exhibits wurtzite phase of aluminum nitride, and
the substrate is a part of a component or is a part of an article or is a component or is an article used in the aerospace or power generation industry, wherein the substrate material is stainless steel or a Ni-based, or Co-based or NiCo-based superalloy material.

6. The coated substrate according to claim 1, wherein 54/46≤Al/Ti≤80/20.

7. A method for producing a coated substrate according to claim 1, comprising producing the at least one layer comprising titanium, aluminum and nitrogen by:
a) depositing a layer comprising titanium, aluminum and nitrogen on at least one surface of the substrate, wherein said layer comprising titanium aluminum and nitrogen is deposited exhibiting wurzite phase of aluminum nitride and having the content of aluminum in relation to the content of titanium satisfy Al/Ti>1, if considering only respective concentrations of aluminum and titanium in atomic percentage and,
b) subjecting the substrate coated as indicated in process step a) to a process in which rutile phase of titanium oxide is formed.

8. The method according to claim 7, wherein step a) is conducted by using physical vapor deposition techniques for the deposition of the layer comprising titanium, aluminum and nitrogen and step b) includes exposing at least a part of the substrate coated as indicated in process step a) to temperatures between 500° C. and 950° C.

9. The method according to claim 8, wherein the physical vapor deposition process is a reactive cathodic arc evaporation process.

10. The method according to claim 9, wherein at least a target composed of aluminum and titanium and having an element composition satisfying Al/Ti>1 in atomic percentage is used as a material source and nitrogen gas is used as a reactive gas during deposition of the layer comprising titanium, aluminum and nitrogen.

11. The method according to claim 10, wherein the at least one target has a composition of Al 60 at. % and Ti 40 at. %.
